(19) United States
(12) Patent Application Publication
(10) Pub. No.: US 2025/0273600 A1
(43) Pub. Date: Aug. 28, 2025

(54) SEMICONDUCTOR DEVICE HAVING A CRACK ARRESTING STRUCTURE AND METHOD OF MANUFACTURING

(71) Applicant: Infineon Technologies Austria AG, Villach (AT)

(72) Inventors: Dirk Priefert, Moers (DE); Soon Huat Niew, Klang (MY); Maria Heidenblut, Schwarzenfeld (DE)

(21) Appl. No.: 19/051,806

(22) Filed: Feb. 12, 2025

(30) Foreign Application Priority Data
Feb. 22, 2024 (DE) 102024105035.7

(51) Int. Cl. H01L 23/58; H01L 21/78; H01L 23/00

(52) U.S. Cl. CPC H01L 23/585; H01L 21/78; H01L 23/562

(57) ABSTRACT

A semiconductor device includes a semiconductor portion including a central region and a peripheral region separating the central region from a lateral chip edge. An interlayer dielectric is formed on a horizontal first main surface of the semiconductor portion. In the peripheral region, a groove extends through the interlayer dielectric. A crack arresting structure includes a first portion formed in the groove. A dielectric layer structure is formed on the interlayer dielectric and the crack arresting structure. The dielectric layer structure and the crack arresting structure are configured such that each horizontal plane intersecting the dielectric layer structure and the lateral chip edge intersects a tilted surface of the dielectric layer structure in the peripheral region.

### TECHNICAL FIELD

The present disclosure relates to a semiconductor device with a crack arresting structure in a peripheral region and a method of manufacturing a semiconductor device with a crack arresting structure.

### BACKGROUND

Following the processing of a semiconductor wafer, wafer dicing cuts a wafer into identical semiconductor dies. Each semiconductor die has a semiconductor body and functional layers of dielectric and metallic materials on opposite main surfaces of the semiconducting portion. The individual semiconductor dies can be encapsulated in chip packages adapted for the use in electronic devices.

Typically, wafer dicing involves mechanical processes like scribing and breaking, or mechanical sawing using a rotating dicing blade. Mechanical wafer dicing is effective along dicing streets (“scribe lines”) that form a regular rectangular grid. Scribing, breaking and sawing along the dicing streets can generate cracks propagating from the dicing street into the adjoining portion of a semiconductor die. Crack stop structures formed along the die edge stop the propagation of cracks into direction of a central die portion.

There is an ongoing need for protecting a central portion of a semiconductor die against defects induced by wafer dicing processes, in particular, mechanical wafer dicing processes.

### SUMMARY

A wafer typically includes layers of dielectric materials with the dielectric layers laterally extending into the dicing streets. Mechanical wafer dicing processes that cut into the dielectric layers generate local mechanical stress. The mechanical stress may damage the internal structure in portions of the dielectric layers along the dicing streets. The damage can result in cracks in a dielectric layer, wherein the cracks propagate in direction of a central region of the semiconductor die. The cracks can adversely affect performance and/or the reliability of an integrated circuit and/or printed circuit board that includes a semiconductor die obtained from the wafer by the wafer dicing process.

According to the present disclosure a semiconductor device includes a semiconductor portion with a central region and a peripheral region separating the central region from a lateral chip edge. An interlayer dielectric is formed on a horizontal first main surface of the semiconductor portion. In the peripheral region, a groove extends through the interlayer dielectric. A crack arresting structure includes a first portion formed in the groove. A dielectric layer structure is formed on the interlayer dielectric and the crack arresting structure, wherein the dielectric layer structure and the crack arresting structure are configured such that each horizontal plane intersecting the dielectric layer structure and the lateral chip edge intersects a tilted surface of the dielectric layer structure in the peripheral region.

As a consequence, no horizontal plane exists in the dielectric layer structure and the interlayer dielectric that intersects the lateral chip edge and spans the crack arresting structure without interruption from a side of the peripheral region oriented to the lateral chip edge to a side oriented to the central region. Interfaces between different solid materials stop the propagation of cracks in the interlayer dielectric and the dielectric layer structure. No or only a very limited number of cracks can extend into the central region.

Since the dielectric layer structure can completely cover the crack arresting structure, the crack arresting structure can be formed from conductive material(s) and in contact with the semiconductor portion without the risk of an electric flashover between the crack arresting structure and other conductive structures through air and/or other materials low with dielectric strength, even if such other conductive structures are formed on the dielectric layer structure or are exposed through openings in the dielectric layer structure.

The present disclosure also relates to a method of manufacturing a semiconductor device. An interlayer dielectric is formed on a first main surface of a semiconductor portion that includes a central region and a peripheral region laterally surrounding the central region. A groove is formed that extends in the peripheral region into the interlayer dielectric. A crack arresting structure is formed that includes a first portion formed in the groove. A dielectric layer structure is formed that covers the interlayer dielectric and the crack arresting structure.

Those skilled in the art will recognize additional features and advantages by reading the following detailed description and viewing the accompanying drawings.

### BRIEF DESCRIPTION OF THE DRAWINGS

The accompanying drawings are provided for further understanding of the embodiments and form an integral part of this description. The drawings illustrate embodiments of semiconductor device and a method of manufacturing a semiconductor device and, together with the description, explain the principles underlying the embodiments. Further embodiments are described in the following detailed description and in the claims. Features of the various embodiments may be combined with each other.

FIGS. 1A and 1B show a simplified vertical and a simplified horizontal cross-section of a semiconductor device with a crack arresting structure according to an embodiment.

FIG. 2 shows a simplified vertical cross-section of a semiconductor device with a crack arresting structure formed in a lower part of a groove in an interlayer dielectric, according to an embodiment.

FIG. 3 shows a simplified vertical cross-section of a semiconductor device with a crack arresting structure overfilling a groove in an interlayer dielectric, according to an embodiment.

FIG. 4 shows a simplified vertical cross-section of a semiconductor device with a crack arresting structure having a first portion formed in a groove in an interlayer dielectric and a second portion formed on the interlayer dielectric outside the groove, according to an embodiment.

FIG. 5 shows a simplified vertical cross-section of another semiconductor device with a crack arresting structure having a first portion formed in a groove in an interlayer dielectric and a second portion formed on the interlayer dielectric outside the groove, according to an embodiment.

FIGS. 6 and 7 show simplified vertical cross-sections of semiconductor devices having a crack arresting structure including a first portion formed in a lower portion of a groove in an interlayer dielectric and a second portion formed on the interlayer dielectric, according to other embodiments with the crack arresting structures having different vertical extents.

FIG. 8 shows a simplified vertical cross-sectional of a semiconductor device with a crack arresting structure having laterally separated portions, according to an embodiment.

FIGS. 9A to 9D show simplified vertical cross-sections of a portion of a semiconductor wafer for illustrating a method of manufacturing a semiconductor device having a crack arresting structure in successive process stages, according to another embodiment.

### DETAILED DESCRIPTION

In the following detailed description, reference is made to the accompanying drawings which form a part of this document and in which certain embodiments of a semiconductor device and a method of manufacturing a semiconductor device are shown as illustrations. Structural or logical changes may be made to the illustrated embodiments without departing from the scope of the present disclosure. For example, features shown or described for one embodiment may be used on or in conjunction with other embodiments, resulting in another embodiment. The present disclosure is intended to include such modifications and variations. The embodiments are described in a manner that should not be construed as limiting the scope of the appended claims. The drawings are not to scale and are for illustrative purposes only. Corresponding elements are designated by the same reference numerals in the various drawings, unless otherwise indicated.

The terms “having”, “containing”, “including”, “comprising” and the like are open-ended, and the terms indicate the presence of certain structures, elements or features but do not preclude the presence of additional elements or features. The articles “a”, “an” and “the” include both the plural and singular, unless the context clearly indicates otherwise.

The term “on” is not to be construed as meaning only “directly on”. Rather, if one element is positioned “on” another element (e.g., a layer is “on” another layer or “on” a substrate), a further component (e.g., a further layer) may be positioned between the two elements (e.g., a further layer may be positioned between a layer and a substrate if the layer is “on” said substrate).

Ranges given for physical dimensions include the boundary values. For example, a range for a parameter y from a to b reads as a≤y≤b. The same holds for ranges with one boundary value like “at most” and “at least”.

An ohmic contact describes a non-rectifying electrical junction between two conductors, e.g., between a semiconductor material and a metal. The ohmic contact has a linear or approximately linear current-voltage (I-V) curve in the first and third quadrant of the I-V diagram as with Ohm's law.

A semiconductor device may include a semiconductor portion including a central region and a peripheral region separating the central region from a lateral chip edge. An interlayer dielectric may be formed on a horizontal first main surface of the semiconductor portion. In the peripheral region a groove may extend through the interlayer dielectric. A crack arresting structure may include a first portion formed in the groove. A dielectric layer structure may be formed on the interlayer dielectric and the crack arresting structure, wherein the dielectric layer structure and the crack arresting structure may be configured such that each horizontal plane intersecting the dielectric layer structure and the lateral chip edge intersects a tilted surface of the dielectric layer structure in the peripheral region.

The semiconductor portion may be a homogenous semiconductor body. Alternatively, the semiconductor portion is a layer of a multi-layer body, for example, the semiconductor layer or a substrate layer of a silicon-on-insulator (SOI) body.

The semiconductor portion may include a central region and a peripheral region laterally surrounding the central region. The peripheral region may laterally separate the central region from the lateral chip edge. The lateral chip edge may include four straight sections, each of them coplanar with a section of a lateral outer surface of the semiconductor portion. The peripheral region can include four sections, each of which extends in a uniform width along one section of the lateral chip edge. the central region, electrical elements and/or electrical circuits of an integrated circuit are formed that define the electrical functionality of the semiconductor device. The integrated circuit may be a high voltage semiconductor device. For example, the functional electrical elements and electrical circuits of a gate driver circuit are formed in the central region. In the peripheral region, functional electrical elements of the integrated circuit may be completely absent.

The semiconductor portion has a horizontal first main surface at a front side. An interlayer dielectric may be formed on the horizontal first main surface. The interlayer dielectric may be directly formed on the first main surface. Alternatively, one or more other layers may be formed between the interlayer dielectric and the first main surface of the semiconductor portion. The interlayer dielectric may have a uniform thickness and/or may be a homogenous layer. Alternatively, the interlayer dielectric may be a layer stack including at least two sublayers of different composition and/or internal structure (German: Gefüge). For example, the interlayer dielectric may include a thermally grown oxide sublayer of the material of the semiconductor portion and one or more sublayers of silicon oxide deposited under different deposition conditions, wherein the thermally grown oxide sublayer is formed directly on the first main surface and the other sublayers are formed successively on the thermally grown oxide sublayer.

The groove in the peripheral region may extend from a top surface of the interlayer dielectric into the interlayer dielectric. The groove may extend through the interlayer dielectric and expose a contact section of the semiconductor portion.

In the groove, the first portion of the crack arresting structure is formed. The crack arresting structure may include only the first portion in the groove. Alternatively, the crack arresting structure may further include a second portion formed outside the groove and in direct contact with the first portion. The first portion of the crack arresting structure may have an approximately uniform thickness directly over a central portion of a bottom of the groove. The second portion of the crack arresting structure may have an approximately uniform thickness above the horizontal top surface of the interlayer dielectric. The horizontal top surface of the interlayer dielectric and a virtual separation plane between the first and second portion of the crack arresting structure may be coplanar. The first portion and the second portion are partly arranged vertically one above the other. The second portion may include two separated sub-portions on opposite sides of the groove.

Alternatively to the second portion or in addition, the crack arresting structure may include a third portion disconnected from the first portion.

The first portion of the crack arresting structure is made of a material other than the interlayer dielectric. For example, the interlayer dielectric is based on a silicon oxide and the crack arresting structure does not contain a compound with silicon and oxygen as main components, e.g., as only main components. The crack arresting structure may be in direct contact with the semiconductor portion at the bottom of the groove and with the interlayer dielectric along the sidewall of the groove.

The dielectric layer structure formed on the interlayer dielectric and the crack arresting structure may be effective as passivation structure and may be in direct contact with the interlayer dielectric along at least a section of the horizontal top surface of the interlayer dielectric. The dielectric layer structure may be in direct contact with the crack arresting structure along the upper surface of the crack arresting structure. The dielectric layer structure may have a uniform thickness over horizontal sections of the interlayer dielectric and the crack arresting structure.

The semiconductor portion, the combination of interlayer dielectric and crack arresting structure, and the dielectric layer structure are vertically stacked one on each other along a vertical direction orthogonal to the first main surface. The lateral chip edge includes the lateral outer surface of the semiconductor portion and lateral sidewalls of the interlayer dielectric and the dielectric layer structure, wherein the lateral sidewalls of the interlayer dielectric and the dielectric layer structure and the lateral outer surface of the semiconductor portion are coplanar.

The dielectric layer structure has horizontal surface sections and tilted surface sections connecting the horizontal surface sections. First tilted surface sections are formed along an interface between a bottom surface of the dielectric layer structure and tilted sidewalls of the crack arresting structure. Second tilted surface sections are formed between horizontal surface sections of the upper surface of the dielectric layer structure. The second tilted surface sections may be formed along interfaces to a package mold that is in direct contact with the upper surface of the dielectric layer structure, and/or along interfaces to ambient air.

An angle between each tilted surface and a horizontal plane parallel to the first main surface may be in a range from 30 degrees to 90 degrees.

When the groove, the interlayer dielectric, the dielectric layer structure and the crack arresting structure are configured in a way that each horizontal plane intersecting the lateral chip edge in the dielectric layer structure intersects a tilted surface of the dielectric layer structure in the peripheral region, no horizontal plane exists that spans the crack arresting structure within the dielectric layer structure without interruption from a side of the peripheral region oriented to the lateral chip edge to a side oriented to the central region.

Each crack in the interlayer dielectric that is generated at the lateral chip edge and propagates in a horizontal plane in direction of the central region ends at the first crack arresting structure that lines or fills the groove. Each horizontal crack in the dielectric layer structure that is generated at the lateral chip edge and that propagates in a horizontal plane ends at one of the tilted surfaces of the dielectric layer structure.

Cracks in the dielectric layer structure and in the interlayer dielectric that are generated at the lateral chip edge and propagate in directions tilted to the horizontal plane, end at the first main surface of the semiconductor portion, at horizontal surfaces of the dielectric layer structure in the peripheral region, and/or at tilted surfaces of the dielectric layer structure in the peripheral region. No cracks or only a very small portion of the cracks propagate into the central region. The dielectric layer structure and the interlayer dielectric for the functional circuits remain unharmed. Device reliability can be improved.

The semiconductor device may include a plurality of grooves and crack arresting bodies formed along one, two, or more frame-like lines surrounding the central region. The grooves and crack arresting bodies may be formed with similar or equal dimensions along each frame-like line and may be equidistant to each other. A distance between neighboring crack arresting bodies may be smaller than a length of the crack arresting bodies along the frame-like line such that a great portion of cracks propagating from the lateral chip edge in direction of the central region end at one of the interfaces of the interlayer dielectric or the dielectric layer structure within the peripheral region.

According to an embodiment, the crack arresting structure may laterally surround the central region.

In particular, the semiconductor device may include one single crack arresting structure forming a continuous frame around the central region. All cracks in the interlayer dielectric and/or the dielectric layer structure propagating essentially straight from the lateral chip edge in direction of the central region end within the peripheral region at one of the interfaces of the interlayer dielectric or the dielectric layer structure.

The material(s) and/or structure of the crack arresting structure is selected such that the crack arresting structure stops cracks propagating in the interlayer dielectric and/or the dielectric layer structure.

According to an embodiment, the crack arresting structure may be formed from a conductive material.

The crack arresting structure may be formed from one or more conductive materials. In particular, the crack arresting structure may have the same composition as conductive lines and/or conductive structures of the integrated circuit formed in the central region, e.g., field plates. The crack arresting structure and the conductive lines and/or conductive structures in the integrated circuit can be formed from different sections of the same conductive layer or layer stack. Formation of the crack arresting structure can be fully compatible with the formation of the conductive lines and/or conductive structures and requires not more than a modification of a mandatory process, but no additional process.

According g to an embodiment, the dielectric layer structure may completely cover a portion of the crack arresting structure that is in direct contact with the semiconductor portion.

When the dielectric layer structure completely covers a crack arresting structure that is formed from conductive material(s) and is in direct contact with the semiconductor portion, and a wafer level test applies a high voltage between the semiconductor portion and an exposed conductive structure of the semiconductor die, the dielectric layer structure prevents any electric flashover through air and/or another material of low dielectric strength between the crack arresting structure and the exposed conductive structure. The exposed conductive structure may be a signal contact pad or a power supply pad formed in the central region.

According to an embodiment, the crack arresting structure may include a second portion formed on the interlayer dielectric, wherein the first portion and the second portion are connected.

Horizontal sections of the first portion and the second portion may have a same vertical extent and a same material configuration. The first portion and the second portion may be different sections of one metallization layer. The metallization layer can include only the first portion and the second portion of the crack arresting structure. Alternatively, the metallization layer may include, in addition to the first and second portions of the crack arresting structure, third sections forming conductive lines and/or conductive structures that electrically connect electric elements in the central region. The metallization layer may be a 3D layer deposited on horizontal surfaces shifted to each other along the vertical direction. The metallization layer may include copper, aluminum and/or a copper aluminum alloy. Formation of the crack arresting structure is based on a modification of the lithographic mask defining the electric connections. No additional process step is required to form the crack arresting structure.

According to an embodiment, a width w0 of the groove and vertical extents w2, w3, w4 of horizontal portions of the interlayer dielectric, the crack arresting structure, and the dielectric structure may be selected such that each horizontal plane intersecting the lateral chip edge in the dielectric layer structure intersects a tilted surface of the dielectric layer structure in the peripheral region at a distance to the lateral chip edge.

As a consequence, no horizontal plane exists that spans the crack arresting structure within the dielectric layer structure from a side of the peripheral region oriented to the lateral chip edge to a side of the peripheral region oriented to the central region without interruption.

According to an embodiment, a difference between a maximum vertical distance wx between an upper surface of the dielectric layer structure and the first main surface and a minimum vertical distance wy between the upper surface of the dielectric layer structure and the first main surface may be greater than or equal to a maximum thickness w4 of the dielectric layer structure.

For wx−wy≥w4 at least two sections of the dielectric layer structure have a vertical shift to each other that is greater than their vertical extent. Within the dielectric layer structure, no horizontal plane can exist that spans the crack arresting structure without interruption from an outer side of the crack arresting structure oriented to the lateral chip edge to an inner side of the crack arresting structure oriented to the central region.

According to an embodiment, a width w0 of the groove may be wide enough such that the dielectric layer structure forms steps directly over the bottom of the groove.

A height of the step may be at least 90% or approximately 100% of the vertical extent w2 of the interlayer dielectric. A slit resulting from the steps laterally separates two vertical portions of the dielectric layer structure. The crack arresting structure blocks with high efficiency a great variety of different crack types.

According to an embodiment, a step height of the steps formed by the dielectric layer structure may be greater than a vertical extent w4 of the dielectric layer structure.

In particular, the lower edge of the dielectric layer structure directly over the groove may be closer to the first main surface of the semiconductor portion (“deeper”) than the upper surface of the crack arresting structure. The crack arresting structure blocks with high efficiency a great variety of different crack types.

If the vertical extent w2 of the interlayer dielectric is greater than the vertical extent w4 of the dielectric layer structure, each linear crack generated at the lateral chip edge in the dielectric layer structure ends at the slit at the latest, even if the vertical extent w4 of the dielectric layer structure is greater than the vertical extent w3 of the horizontal portions of the crack arresting structure.

According to an embodiment, the crack arresting structure may include a third portion formed on the interlayer dielectric in the peripheral portion, wherein the third portion is separated from the first portion.

The third portion can be structurally and electrically separated from the semiconductor portion, the first portion of the crack arresting structure and, if applicable, from the second portion of the crack arresting structure. In particular, the third portion may electrically float or may be electrically connected to a conductive structure that has an electric potential different an from electric potential of the semiconductor portion. The third portion may be formed between the first portion and the lateral chip edge and/or between the first portion and the central region. The third portion may have the same vertical extent as the second portion and may be a further section of the metallization layer from which the first portion or the first portion and the second portion are formed. The third portion may provide a further crack stop for cracks propagating in the interlayer dielectric and/or the dielectric layer structure from the lateral chip edge in direction of the central portion.

The semiconductor device may include a plurality of third portions, each formed on another auxiliary line surrounding the central region. Each auxiliary line may include four linear sections, each parallel to one of the four lateral chip surfaces. The total portion of an auxiliary line occupied with third portions may be greater than the total portion of the auxiliary line between the third portions.

According to an embodiment, a gap may extend through the dielectric layer structure above the third portion of the crack arresting structure.

The gap may expose a portion of the upper surface of the third portion of the crack arresting structure. The gap and the third portion of the crack arresting structure may complement each other to a heterogeneous vertically extended crack stop completely disrupting interlayer the dielectric and the dielectric layer structure. Each horizontal crack originating at the lateral chip edge and propagating in the dielectric layer structure and/or the interlayer dielectric at an arbitrary angle to the horizontal plane in direction of the central region ends at the gap or the third portion, irrespective of a ratio between the vertical extent w3 of the crack arresting structure and the vertical extent w4 of the dielectric layer structure.

In case a wafer level test applies a high voltage between the semiconductor portion and an exposed conductive structure formed in the central region, the dielectric layer structure prevents any electric flashover through air and/or any other dielectric material with lower dielectric strength than the dielectric layer structure between the first and second portions of the crack arresting structure on the one hand and other conductive structures formed on or exposed by openings in the dielectric layer structure on the other hand. Since the third portion of the crack arresting structure is disconnected from the potential of the semiconductor portion, no electric flashover occurs through the gap.

According to an embodiment a vertical extent w4 of a horizontal portion of the dielectric layer structure may be greater than a vertical extent w3 of a horizontal portion of the crack arresting structure.

In addition, when a combined vertical extent w34 of the crack arresting structure and the dielectric layer structure may be smaller than the vertical extent w2 of the interlayer dielectric so that the slit between vertical portions of the dielectric layer structure extends into the groove in the interlayer dielectric the crack arresting structure provides highly efficient crack arresting for various types of cracks.

According to an embodiment, the third portion of the crack arresting structure may laterally surround the central region.

In particular, the crack arresting structure may include one single third portion forming a continuous frame around the central region. All cracks in the dielectric layer structure originating at or near the lateral chip edge and propagating essentially straight and/or planar in direction of the central region end within the peripheral region at one of the interfaces of the dielectric layer structure.

A method of manufacturing a semiconductor device may include forming an interlayer dielectric on a first main surface of a semiconductor portion, wherein the semiconductor portion comprises a central region and a peripheral region laterally surrounding the central region. A groove may be formed that extends into the interlayer dielectric in the peripheral region.

A crack arresting structure may be formed, wherein a first portion of the crack arresting structure is formed in the groove. A dielectric layer structure may be formed that covers the interlayer dielectric and the crack arresting structure is formed.

According to an embodiment, a conductive structure may be formed in the central region, wherein a metallization layer is deposited on the interlayer dielectric and patterned to simultaneously form, from sections of the metallization layer, the conductive structure in the central region and the crack arresting structure in the peripheral region.

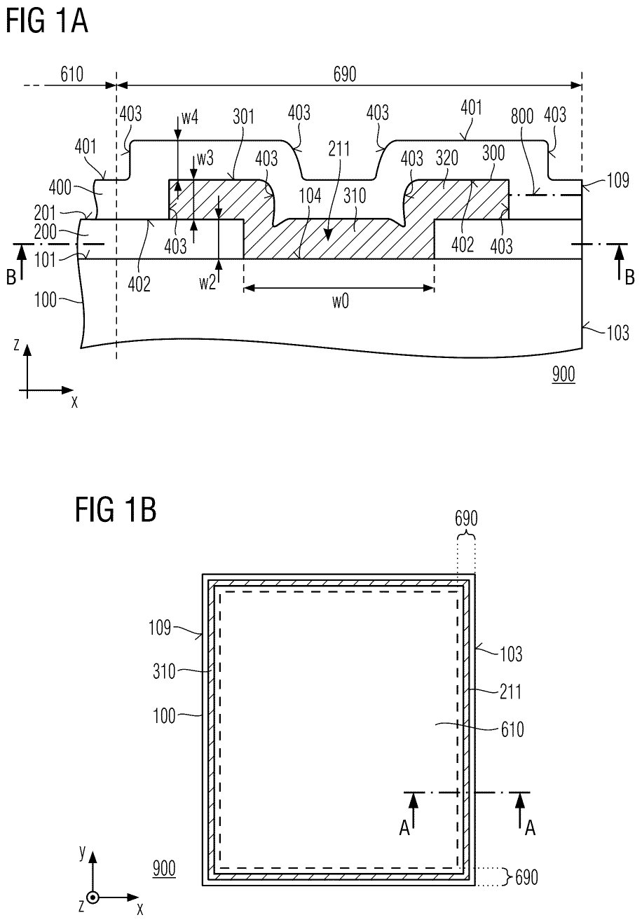

FIG. 1A shows a vertical cross-section through a portion of a semiconductor device 900, for which FIG. 1B shows a horizontal cross-section.

The semiconductor device 900 includes a semiconductor portion 100. The semiconductor portion 100 is a substrate layer of a multi-layer body that also includes a semiconductor layer and an insulator layer separating the substrate layer and the semiconductor layer in device regions of the multi-layer body. Alternatively, the semiconductor portion 100 may be a self-supporting single semiconductor base.

The semiconductor portion 100 is based on a single crystalline semiconductor. The single crystalline semiconductor includes, as group main constituents, IV elemental semiconductors e.g. silicon (Si) or germanium (Ge), group IV compound semiconductors, e.g. silicon carbide (SiC) or silicon germanium (SiGe), or group III-V semiconductors such as gallium nitride (GaN), aluminum gallium nitride (AlGaN) and gallium arsenide (GaAs), by way of example.

The semiconductor portion 100 has a first main surface 101 on a front side and an opposite second main surface on the rear side. The first main surface 101 and the second main surface have the same shape and size and run parallel to each other. A lateral outer surface 103 of the semiconductor portion 100 connects the edge of the first main surface 101 and the edge of the second main surface.

The first main surface 101 is planar and may be continuous or may include two or more coplanar surface sections laterally separated by one or more trenches extending from the front side into the semiconductor portion 100. The first main surface 101 extends along a horizontal plane defined by an x axis and a y axis extending orthogonal to the x axis. A normal to the first main surface 101 defines a vertical direction along a z axis. The semiconductor portion 100 has a rectangular shape in the horizontal plane. The lateral outer surface 103 extends in the vertical direction.

The semiconductor portion 100 includes a central region 610 and a peripheral region 690 laterally surrounding the central region 610. The peripheral region 690 laterally separates the central region 610 from a lateral chip edge 109. The lateral chip edge 109 includes four straight sections, each of them coplanar with a section of the lateral outer surface 103 of the semiconductor portion 100.

The peripheral area 690 has four sections, each of which has uniform width. The four sections of the peripheral area 690 can have the same width. The central region 610 includes the electrical elements and electric circuits of a gate driver circuit. The peripheral region 690 is devoid of functional elements of the gate driver circuit.

An interlayer dielectric 200 is formed on the first main surface 101. The interlayer dielectric 200 is a homogenous layer with a uniform vertical extent w2. The interlayer dielectric 200 is in direct contact with the semiconductor portion 100 and includes or consists of silicon oxide(s), e.g., deposited SiO₂ or a combination of thermal and deposited SiO₂. The density of the silicon oxide is uniform or varies along the vertical direction. Alternatively, the interlayer dielectric 200 includes two or more dielectric sub-layers, wherein at least one of the dielectric sub-layers includes or consists of thermal and/or deposited silicon oxide. The vertical extent w2 of the interlayer dielectric is in a range from 100 nm to 3 μm, e.g., 500 nm to 1.5 μm.

In the peripheral region 690, a groove 211 having a groove width w0 extends through the interlayer dielectric 200 down to the first main surface 101. The groove 211 forms an opening in the interlayer dielectric 200 and exposes a contact section 104 of the first main surface 101. The groove width w0 is in a range from 200 nm to 8 μm, e.g., from 500 nm to 5 μm. As illustrated in FIG. 1B, the groove 211 forms a closed rectangular frame around the central region 610.

A crack arresting structure 300 includes a first portion 310 that is formed in the groove 211 in direct contact with the contact section 104. A second portion 320 of the crack arresting structure 300 is formed outside the groove 211 on a section of the interlayer dielectric 200 directly adjoining the groove 211. The first portion 310 and the second portion 320 are structurally and electrically connected, may form a contiguous layer and have the same vertical extent w3. The vertical extent w3 is in a range from 250 nm to 15 μm.

As illustrated in FIG. 1B, the crack arresting structure 300 may surround the central region 610 and form a substantially closed rectangular frame around the central region 610, wherein the edges of the crack arresting structure 300 may be rounded. Alternatively, the crack arresting structure 300 may surround the central region 610 and form a randomly shaped closed frame, e.g. a circular or elliptic frame or a rectangular-like frame with two 45° angles next to each other replacing each 90° angle.

The material of the crack arresting structure 300 may be an elemental metal, a metal compound, metal alloy and/or highly conductive semiconductor material. For example, the crack arresting structure 300 consists of a single layer that includes or consists of aluminum or an aluminum alloy. Alternatively, the crack arresting structure 300 may include a stack of more than one layer, e.g. more than one metal layer. For example, the crack arresting structure 300 includes a plug containing tungsten plus contact and/or barrier layers like titanium, titanium silicide, titanium nitride in combination with an aluminum or aluminum alloy formed as an overlapping cover after a CMP of the plug material(s). Along the contact section 104, a heavily doped region in the semiconductor portion 100 and the crack arresting structure 300 form an ohmic contact.

A dielectric layer structure 400 is formed in direct contact with a horizontal top surface 201 of the interlayer dielectric 200, tilted sidewalls of the crack arresting structure 300 and a horizontal upper surface 301 of the crack arresting structure 300. The dielectric layer structure 400 may be a homogenous layer or may include two or more sub-layers of different insulating materials. For example, the dielectric layer structure 400 includes a first sub-layer of doped silicate glass, e.g. PSG (phosphorous silicate glass), e.g. a BPSG (boron phosphorous silicate glass), and a second sub-layer containing silicon and nitrogen, e.g. Si₃N₄, wherein the second sub-layer is formed on the first sub-layer. A polymer layer (not illustrated) may be formed on top of the dielectric structure 400. The polymer layer may consist of or contain a polyimide.

Horizontal portions of the dielectric layer structure 400 have a uniform vertical extent w4 over horizontal sections of the interlayer dielectric 200 and the crack arresting structure 300. The total vertical extent w4 of the dielectric layer structure 400 is in a range from 250 nm to 3 μm.

The dielectric layer structure 400 has a bottom surface 402 with first sections in contact with the interlayer dielectric 200 and second sections in contact with the crack arresting structure 300, and an upper surface 401 averted from the interlayer dielectric 200 and the crack arresting structure 300. The bottom surface 402 includes horizontal sections above horizontal sections of the interlayer dielectric 200 and the crack arresting structure 300, and tilted surfaces 403 connecting the horizontal sections. The upper surface 401 includes horizontal sections above horizontal sections of the interlayer dielectric 200 and the crack arresting structure 300, and tilted surfaces 403 connecting the horizontal sections. An angle between any of the tilted surface 403 and the horizontal plane may be in a range from 30 degrees to 90 degrees. Transitions between the tilted surfaces and horizontal sections can be rounded.

A lateral chip edge 109 includes the lateral outer surface 103 of the semiconductor portion 100 and vertical end faces of the interlayer dielectric 200 and the dielectric layer structure 400. The lateral chip edge 109, the lateral outer surface 103 of the semiconductor portion 100, and the vertical end faces of the interlayer dielectric 200 and the dielectric layer structure 400 are coplanar.

The groove 211, the interlayer dielectric 200, the dielectric layer structure 400 and the crack arresting structure 300 are configured such that each horizontal plane 800 that intersects the dielectric layer structure 400 and the lateral chip edge 109 intersects a tilted surface 403 of the dielectric layer structure 400 in the peripheral region 690.

In particular, the groove width w0, the vertical extent w2 of the interlayer dielectric 200, the vertical extent w3 of the crack arresting structure, and the vertical extent w4 of the dielectric layer structure 400 are selected such that each horizontal plane 800 intersecting the lateral chip edge 109 at a level of the dielectric layer structure 400 intersects at least one of the tilted surfaces 403 of the dielectric layer structure 400 in the peripheral region 690 and at a distance to the lateral chip edge 109.

Then there is no horizontal plane within the dielectric layer structure 400 that spans the crack arresting structure 300 without interruption from a portion of the peripheral region 690 that is oriented to the lateral chip edge 109 to a portion of the peripheral region 690 that is oriented to the central region 610.

Since the internal structure (German: Gefüge) of the material of the crack arresting structure 300 differs from the internal structure of the interlayer dielectric 200 and the dielectric layer structure 400, each crack in the interlayer dielectric 200 that is generated at the lateral chip edge 109 and propagates in a horizontal plane ends at the first crack arresting structure 300 that lines the groove 211. Each horizontal crack that is generated at the lateral chip edge 109 and that propagates in the dielectric layer structure 400 in a horizontal plane ends at one of the tilted surfaces 403 of the dielectric layer structure 400.

Cracks in the dielectric layer structure 400 and in the interlayer dielectric 200 that are generated at the lateral chip edge 109 and that propagate in directions tilted to the horizontal plane end at the first main surface 101 of the semiconductor portion 100, the first crack arresting structure 300 or at tilted surfaces 403 or horizontal surfaces of the dielectric layer structure 400 within the peripheral region 690. No cracks propagate into the central region 610.

The dielectric layer structure 400 completely covers the crack arresting structure 300. When a crack arresting structure 300 formed of conductive material(s) is in direct contact with the semiconductor portion 100 and a high voltage is applied between the semiconductor portion 100 and an exposed conductive structure on the front side of the semiconductor device 900 during a wafer level test, the dielectric layer structure 400 prevents any electric flashover through the air between the crack arresting structure 300 and the exposed conductive structure.

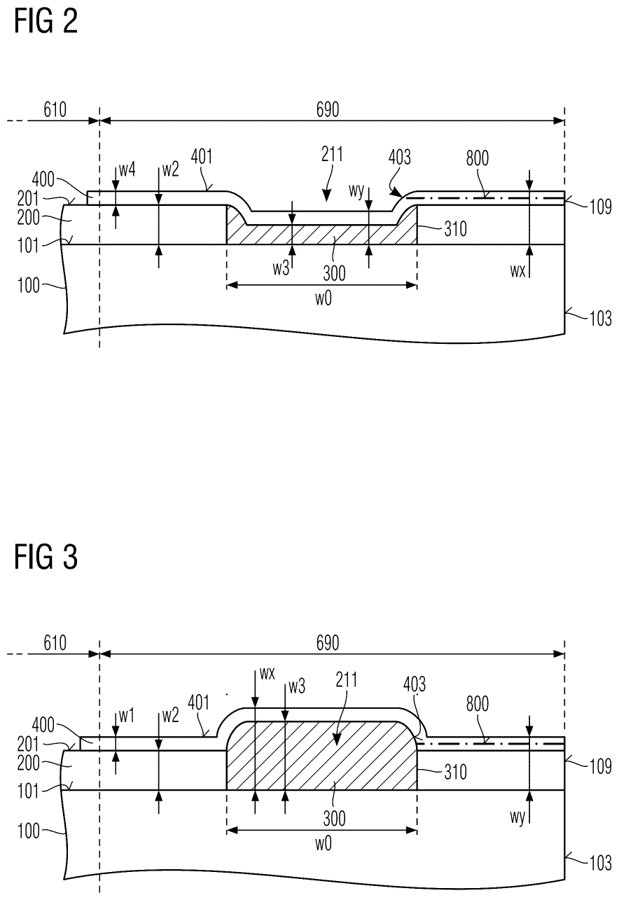

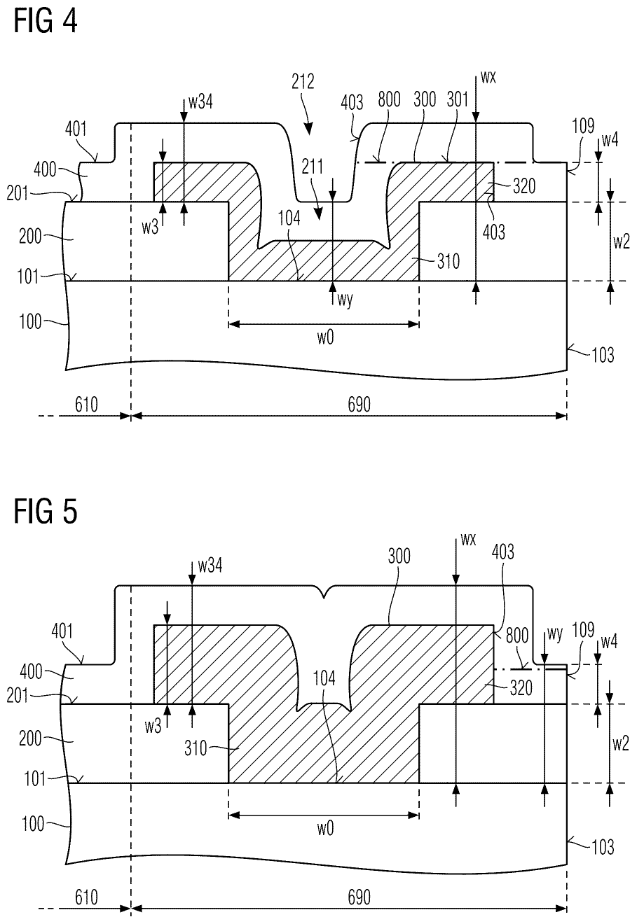

In FIG. 2 and in FIG. 3, the crack arresting structure 300 includes only a first portion 310 completely formed directly above the bottom of the groove 211. The crack arresting structures 300 do not laterally extend beyond the groove 211 and do not include a portion formed on the horizontal top surface 201 of the interlayer dielectric 200. The crack arresting structures 300 can completely cover the sidewalls of the groove 211 or may be formed at a distance to the sidewalls of the groove 211.

In FIG. 2, the vertical extent w3 of the crack arresting structure 300 is smaller than the vertical extent w2 of the interlayer dielectric 200. A maximum vertical distance wx between the upper surface 401 of the dielectric layer structure 400 and the first main surface 101 is outside the groove 211. A minimum vertical distance wy between the upper surface 401 of the dielectric layer structure 400 and the first main surface 101 is inside the groove 211. The difference wx−wy is greater than the maximum thickness w4 of the dielectric layer structure 400.

In FIG. 3, the vertical extent w3 of the crack arresting structure 300 is greater than the vertical extent w2 of the interlayer dielectric 200. The maximum vertical distance wx between the upper surface 401 of the dielectric layer structure 400 and the first main surface 101 is inside the groove 211. A minimum vertical distance wy between the upper surface 401 of the dielectric layer structure 400 and the first main surface 101 is outside the groove 211. The difference wx−wy is greater than the maximum thickness w4 of the dielectric layer structure 400.

In both FIG. 2 and FIG. 3, each horizontal plane 800 intersecting the lateral chip edge 109 at a level of the dielectric layer structure 400 intersects at least one of the tilted surfaces 403 of the dielectric layer structure 400 in the peripheral region 690 at a distance to the lateral chip edge 109.

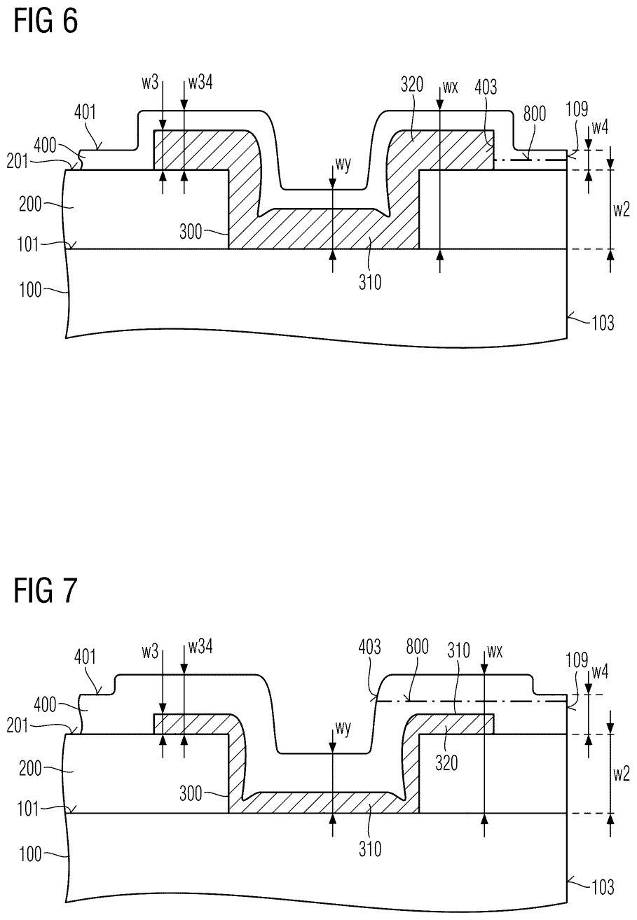

FIGS. 4 to FIG. 7 show further examples with a groove width w0 and vertical extents w2, w3, w4 of horizontal portions of the interlayer dielectric 200, the crack arresting structure 300, and the dielectric layer structure 400 being selected such that each horizontal plane 800 intersecting the lateral chip edge 109 at a level of the dielectric layer structure 400 intersects a tilted surface 403 of the dielectric layer structure 400 at a distance to the lateral chip edge in the peripheral region 690.

In particular, a difference between a maximum vertical distance wx between an upper surface 401 of the dielectric layer structure 400 and the first main surface 101 and a minimum vertical distance wy between the upper surface 401 of the dielectric layer structure 400 and the first main surface 101 is greater than a maximum thickness w4 of the dielectric layer structure 400.

In particular, at least two horizontal sections of the dielectric layer structure 400 have a vertical shift to each other that is greater than the vertical extent w4 of the dielectric layer structure 400. Within the dielectric layer structure 400, no horizontal plane 800 can exist that intersects the lateral chip edge 109 at the level of the dielectric layer structure 400 and that spans the crack arresting structure 300 without interruption from the outer side of the peripheral region 690 to the inner side.

In FIG. 4, the groove width w0 and the vertical extensions w3, w4 are selected so that above the contact section 104 a slit 212 is formed that laterally separates two opposing vertical portions of the dielectric layer structure 400. Each of the two vertical portions of the dielectric layer structure 400 connects a horizontal portion formed on the second portion 320 of the crack arresting structure 300 with a horizontal portion formed on the first portion 310 of the crack arresting structure 300. A combined vertical extent w34 of the crack arresting structure 300 and the dielectric layer structure 400 is less than half of the groove width (w3+w4<0.5*w0). Each horizontal plane 800 in the dielectric layer structure 400 that intersects the lateral chip edge 109 at the level of the dielectric layer structure 400 ends at a tilted surface 403 of the dielectric layer structure 400 along the crack arresting structure 300 or the slit 212.

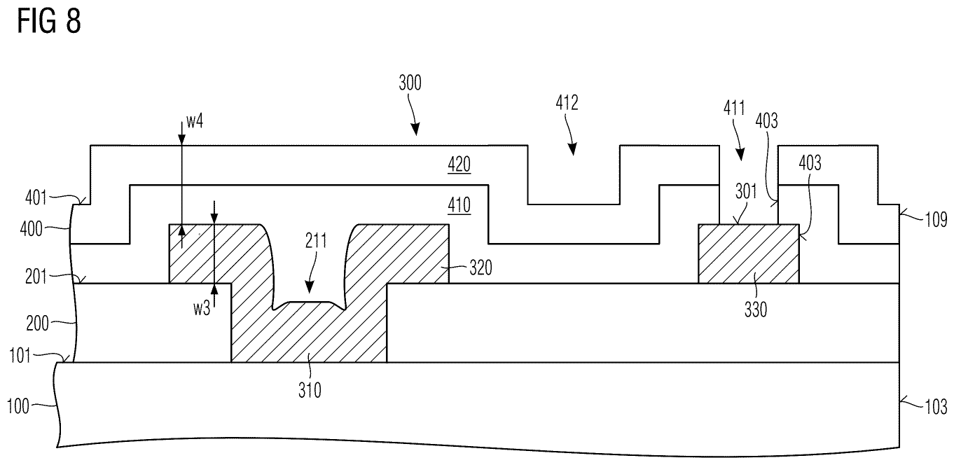

In FIG. 5, the groove width w0 and the vertical extensions w3, w4 are selected so that above the contact section 104 the dielectric layer structure 400 forms no slit or only a shallow slit. The combined vertical extent w34 of the crack arresting structure 300 and the dielectric layer structure 400 is greater than half of the groove width (w3+w4>0.5*w0). Each horizontal plane 800 in the dielectric layer structure 400 that intersects the lateral chip edge 109 at a level of the dielectric layer structure 400 ends at a tilted surface 403 of the dielectric layer structure 400 along the crack arresting structure 300.

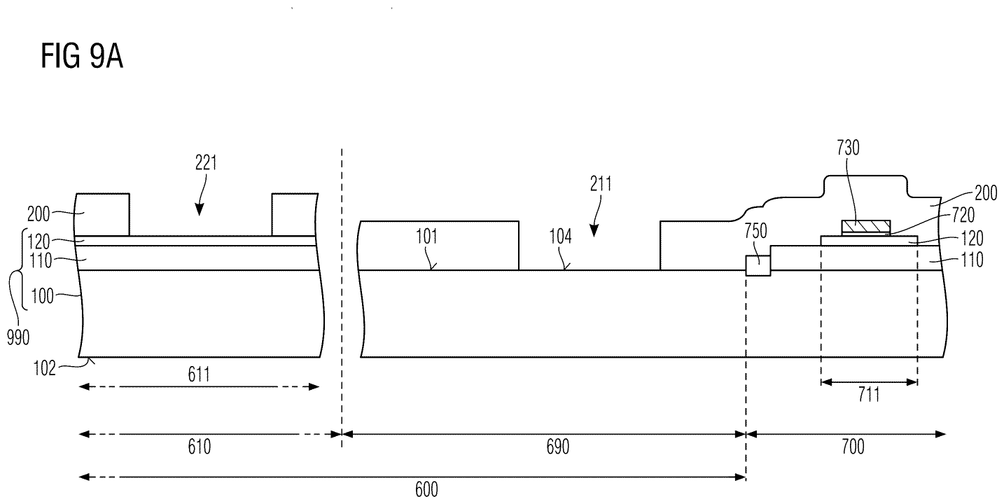

In FIG. 6, the combined vertical extent w34 of the crack arresting structure 300 and the dielectric layer structure 400 is less than half of the groove width (w3+w4<0.5*w0), and the vertical extent w4 of the dielectric layer structure 400 is smaller than the vertical extent w3 of the crack arresting structure 300 (w4<w3). Each horizontal plane 800 in the dielectric layer structure 400 that intersects the lateral chip edge 109 ends at a tilted surface 403 of the dielectric layer structure 400 along the crack arresting structure 300.

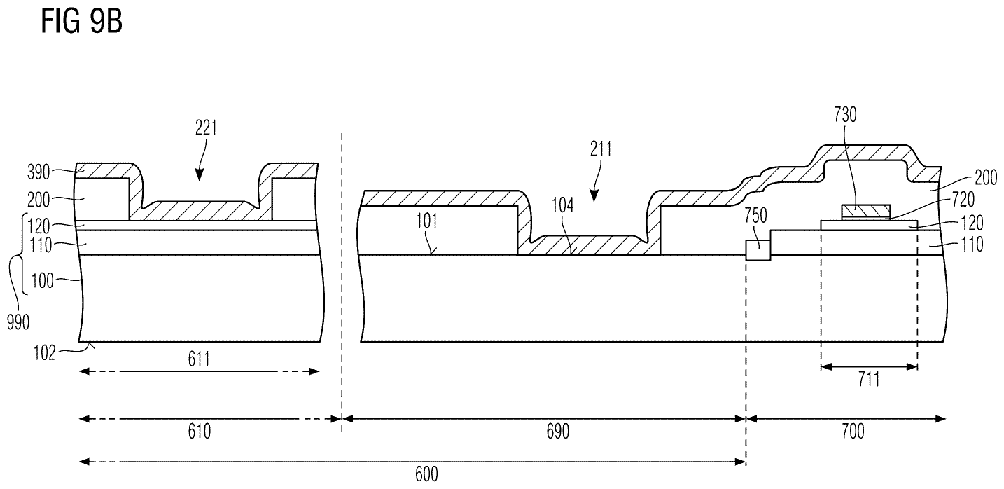

In FIG. 7, the combined vertical extent w34 of the crack arresting structure 300 and the dielectric layer structure 400 is less than half of the groove width (w3+w4<0.5*w0), and the vertical extent w4 of the dielectric layer structure 400 is greater than the vertical extent w3 of the crack arresting structure 300 (w4>w3). Each horizontal plane 800 in the dielectric layer structure 400 that intersects the lateral chip edge 109 at the level of the dielectric layer structure 400 ends at a tilted surface 403 of the dielectric layer structure 400 along the crack arresting structure 300, or a tilted surface 403 of the slit 212 formed by the dielectric layer structure 400 above the groove 211.

In both FIG. 6 and FIG. 7, the vertical extent of the slit 212 is greater than a vertical extent w4 of the dielectric layer structure 400 so that a portion of the upper surface 401 of the dielectric layer structure 400 directly over the groove 211 is closer to the first main surface 101 (“deeper”) than the horizontal upper surface 301 of the crack arresting structure 300. In this way, the slits 212 can contribute to a greater extent to preventing the spread of different types of cracks into the central region 610.

If the vertical extent w2 of the interlayer dielectric 200 is greater than the combined vertical extent w34 of the crack arresting structure 300 and the dielectric layer structure 400 as illustrated in FIG. 6 and FIG. 7, the probability that various types of cracks generated at the lateral chip edge 109 in the dielectric layer structure 400 end at one of the sidewalls of the slit 212 is high. This holds irrespective of a ratio between the vertical extent w4 of the dielectric layer structure 400 and the vertical extent w3 of the horizontal portions of the crack arresting structure 300 as illustrated in FIG. 7.

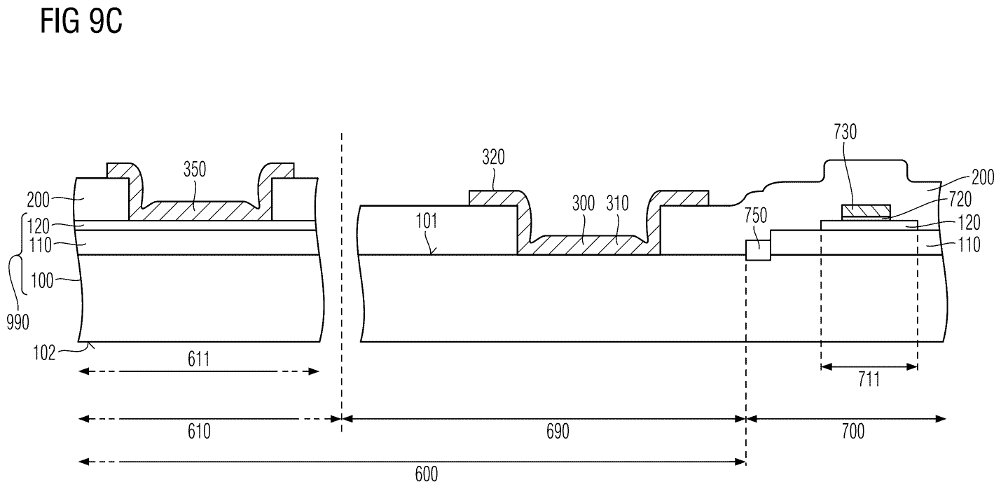

FIG. 8 shows a crack arresting structure 300 that includes a third portion 330 formed on the interlayer dielectric 200 in the peripheral portion 690.

The first and second portions 310, 320 can have any of the configurations as described with reference to FIG. 2 to FIG. 7. The third portion 330 is structurally and electrically separated from the first portion 310 and the second portion 320 of the crack arresting structure 300. The third portion 330 is also electrically separated from the semiconductor portion 100 and electrically floats.

FIG. 8 shows the third portion 330 between the first portion 310 and the lateral chip edge 109 but the third portion 330 may just as well be between the first portion 310 and the central region 610. The third portion 330 has the same vertical extent w3 as the second portion 320. The first portion 310, the second portion 320 and the third portion 330 are different sections of the same metallization layer. A lateral distance between the second portion 320 and the third portion 330 is great enough so that a further slit 412 extends from the front side into the dielectric layer structure 400 between the second portion 320 and the third portion 330. The third portion 330 laterally surrounds the central region 610.

The dielectric layer structure 400 includes a first sub-layer 410 formed directly on the interlayer dielectric 200 and the crack arresting structure 300 and a second sub-layer 420 formed on the first sub-layer 410. The first sub-layer 410 includes or consists of doped silicate glass, e.g. PSG. The second sub-layer 420 contains silicon and nitrogen as main components, e.g., Si₃N₄.

A gap 411 extends through the dielectric layer structure 400 above the third portion 330 of the crack arresting structure 300. The gap 411 exposes a portion of the horizontal upper surface 301 of the third portion 330 of the crack arresting structure 300. The gap 411 and the third portion 330 of the crack arresting structure 300 complement each other to a vertically extended crack stop disrupting the interlayer dielectric 200 and the dielectric layer structure 400. Any type of linear, non-linear, planar or non-planar crack originating at the lateral chip edge 109 in the interlayer dielectric 200 or the dielectric layer structure 400 and propagating inwardly ends at a sidewall of the gap 411 or at a tilted surface of the third portion 330.

If a high voltage is applied between the semiconductor portion 100 and an exposed conductive structure in the central region 610 during a wafer-level test, the dielectric layer structure 400 prevents electrical flashover through air between the first and second portions 310, 320 of the crack arresting structure 300 on the one hand and the exposed conductive structures on the other hand. Since the third portion 330 of the crack arresting structure 300 is electrically separated from the potential of the semiconductor portion 100, there is no electrical flashover through the gap 411.

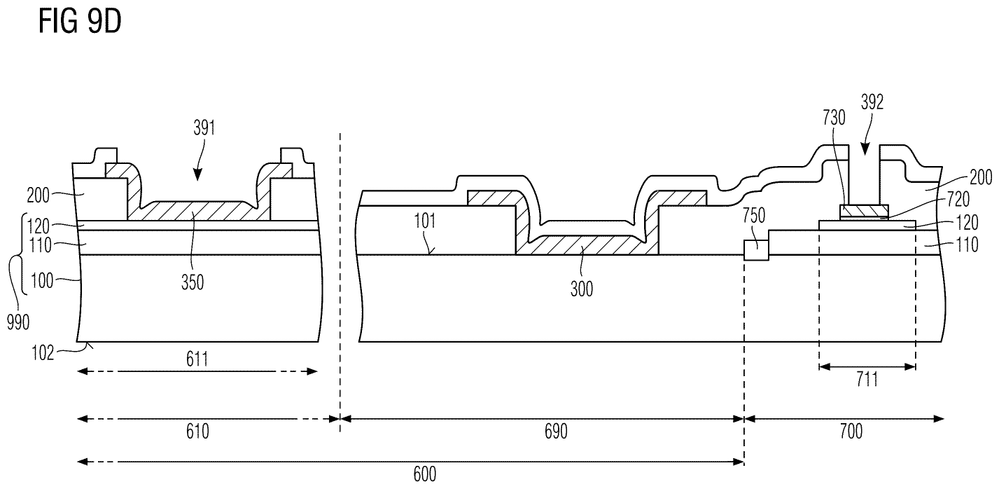

FIG. 9A to FIG. 9D illustrate a method of manufacturing a semiconductor device 900 as shown in any one of FIG. 1A to FIG. 8. The semiconductor devices 900 having one of the crack arresting structures 300 of FIG. 1A to FIG. 8 can be manufactured based on the method illustrated in FIG. 9A to FIG. 9D.

An SOI substrate 990 includes a plurality of chip areas 600 separated by a grid-shaped dicing region 700. The SOI substrate 900 may include a substrate layer, an insulator layer, and a semiconductor layer (device layer). The insulator layer may be a silicon oxide layer that insulates the device layer from the substrate layer. The substrate layer may be a monocrystalline silicon layer. A thickness of the substrate layer may be in a range from 20 μm to 200 μm. The device layer may be a monocrystalline silicon layer. The device layer may have a thickness of 100 nm to 250 nm.

Each chip area 600 includes a central region 610 and a peripheral region 690, wherein the peripheral region 690 surrounds the central region 610 and separates the central region 610 from the neighboring dicing region 700. The central region 610 includes laterally separated application device regions 611. The dicing region 700 includes laterally separated test device regions 711.

The SOI substrate 990 includes a continuous semiconductor portion 100 forming a substrate layer of uniform thickness that forms the common base for all chip areas 600. In each application device region 611 and test device region 711, the SOI substrate 990 includes a semiconductor layer 120 and an insulator layer 110 separating the semiconductor layer 120 and the semiconductor portion 100. The semiconductor layer 120 or the semiconductor layer 120 and the insulator layer 110 are absent in the illustrated portion of the peripheral region 690.

The illustrated test device region 711 includes a field effect transistor with source region and drain region being formed in the semiconductor layer 120. A gate dielectric 720 is formed on the semiconductor layer 120 and separates the semiconductor layer 120 and a gate electrode 730 being formed on the gate dielectric 720. Field oxide structures 750 may be formed in the first main surface 101 along lateral edges of laterally separated portions of the insulator layer 110.

The illustrated application device region 711 includes a semiconductor element with doped regions formed in the semiconductor layer 120.

One or more dielectric materials are deposited on the SOI substrate 990 to form one or more dielectric layers. The deposited materials are patterned by a photolithography process to form an interlayer dielectric 200, wherein openings are formed in the interlayer dielectric 200.

FIG. 9A shows the patterned interlayer dielectric 200. In the application device region 611, portions of the interlayer dielectric 200 are formed directly on the semiconductor layer 120. In the test device regions 711, portions of the interlayer dielectric 200 are formed directly on the field oxide structures 750, the semiconductor layer 120, the insulator layer 110, and the gate electrode 730.

The openings in the interlayer dielectric 200 include a groove 211 that extends in the peripheral region 690 through the interlayer dielectric 200 and exposes a contact section 104 of the first main surface 101, and a contact trench 221 that extends in the central region 610 through the interlayer dielectric 200 and exposes a contact section of the semiconductor layer 120.

One or more conductive materials are deposited on the interlayer dielectric 200 to form a continuous metallization layer 390. The conductive material may include or consist of aluminum.

FIG. 9B shows the continuous metallization layer 390 lining the groove 211 and the contact trench 221 and covering the contact section 104 of the first main surface 101 and the contact section of the semiconductor layer 120. In addition, the continuous metallization layer covers a horizontal top surface 201 of the interlayer dielectric 200. Horizontal sections of the continuous metallization layer 390 have the same, uniform vertical extent.

The continuous metallization layer 390 is patterned by a photolithography process to form a crack arresting structure in the peripheral region 690 and a contact structure in the application device region 611, wherein the contact structure in the central region 610 and the crack arresting structure in the peripheral region 690 are simultaneously formed from different sections of the continuous metallization layer 390 of FIG. 9B.

As illustrated in FIG. 9C, the crack arresting structures 300 in the peripheral region 690 includes a first portion 310 formed in the groove 211 and a second portion 320 formed outside the groove 211. Vertical portions of the crack arresting structure 300, which are formed along the groove sidewalls, connect horizontal portions of the crack arresting structure 300 on the contact section 104 and the horizontal top surface 201 of the interlayer dielectric 200.

Accordingly, the contact structure 350 in the central region 690 includes a first portion formed in the contact trench 221 and a second portion formed outside the contact trench 221. Vertical portions of the contact structure 350, which are formed along the contact trench sidewalls, connect horizontal portions of the contact structure 350 on the contact section of the semiconductor layer 120 and the horizontal top surface 201 of the interlayer dielectric 200.

One or more dielectric materials are deposited to form one or more dielectric layers. The deposited materials are patterned by a photolithography process to form a dielectric layer structure 400, wherein the photolithography process defines openings in the dielectric layer structure 400. The openings in the dielectric layer structure 400 expose conductive structures.

According to FIG. 9D, the dielectric layer structure 400 covers the interlayer dielectric 200 and the crack arresting structure 300 in the peripheral regions 690. A first opening 391 in the dielectric layer structure 400 exposes the contact structure 350 in the application device region 611. A second opening 392 in the dielectric layer structure 400 extends through the interlayer dielectric 200 and exposes the gate electrode 730 in the test device region 711 of the dicing region 700.

A wafer level test is performed. Test needles contact a rear side of the semiconductor portion 100, the gate electrodes 730 and the contact structures 350. When a high voltage is applied through the test needles between the semiconductor portion 100 and the contact structure 350, the dielectric layer structure 400 prevents electric flashover through air between the crack arresting structure 300 and the contact structure 350.

A mechanical dicing process separates the chip areas 600 by sawing or by scribing and breaking the SOI substrate along dicing streets in the dicing region 700. The mechanical dicing process removes at least a part of the material in the dicing region 700. The crack arresting structure 300 prevents cracks generated by the dicing process in the interlayer dielectric 200 and/or the dielectric layer structure 200 from reaching the central region 610.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising:
a semiconductor portion comprising a central region and a peripheral region separating the central region from a lateral chip edge;
an interlayer dielectric on a horizontal first main surface of the semiconductor portion, wherein a groove extends through the interlayer dielectric in the peripheral region;
a crack arresting structure comprising a first portion in the groove; and
a dielectric layer structure on the interlayer dielectric and the crack arresting structure, wherein the dielectric layer structure and the crack arresting structure are configured such that each horizontal plane intersecting the dielectric layer structure and the lateral chip edge intersects a tilted surface of the dielectric layer structure in the peripheral region.

2. The semiconductor device of claim 1, wherein the crack arresting structure laterally surrounds the central region.

3. The semiconductor device of claim 1, wherein the crack arresting structure is formed from a conductive material.

4. The semiconductor device of claim 1, wherein the dielectric layer structure completely covers a portion of the crack arresting structure in direct contact with the semiconductor portion.

5. The semiconductor device of claim 1, wherein the crack arresting structure further comprises a second portion on the interlayer dielectric, and wherein the first portion and the second portion are connected.

6. The semiconductor device of claim 1, wherein a width of the groove and vertical extents of horizontal portions of the interlayer dielectric, the crack arresting structure, and the dielectric layer structure are selected such that each horizontal plane intersecting the dielectric layer structure and the lateral chip edge intersects the tilted surface of the dielectric layer structure in the peripheral region at a distance to the lateral chip edge.

7. The semiconductor device of claim 1, wherein a difference between a maximum vertical distance between an upper surface of the dielectric layer structure and the first main surface and a minimum vertical distance between the upper surface of the dielectric layer structure and the first main surface is greater than a maximum thickness of the dielectric layer structure.

8. The semiconductor device of claim 1, wherein a width of the groove is such that the dielectric layer structure forms steps directly over the bottom of the groove.

9. The semiconductor device of claim 8, wherein a step height of the steps formed by the dielectric layer structure is greater than a vertical extent of the dielectric layer structure.

10. The semiconductor device of claim 1, wherein the crack arresting structure further comprises a third portion on the interlayer dielectric in the peripheral portion, and wherein the third portion is separated from the first portion.

11. The semiconductor device of claim 10, wherein a gap extends through the dielectric layer structure above the third portion of the crack arresting structure.

12. The semiconductor device of claim 10, wherein a vertical extent of a horizontal portion of the dielectric layer structure is greater than a vertical extent of a horizontal portion of the crack arresting structure.

13. The semiconductor device of claim 10, wherein the third portion laterally surrounds the central region.

14. A method of manufacturing a semiconductor device, the method comprising:
forming an interlayer dielectric on a first main surface of a semiconductor portion, wherein the semiconductor portion comprises a central region and a peripheral region laterally surrounding the central region;
forming a groove extending in the peripheral region into the interlayer dielectric;
forming a crack arresting structure comprising a first portion formed in the groove; and
forming a dielectric layer structure covering the interlayer dielectric and the crack arresting structure.

15. The method of claim 14, further comprising:
forming a conductive structure in the central region, wherein a metallization layer is deposited on the interlayer dielectric and patterned to simultaneously form the conductive structure in the central region and the crack arresting structure in the peripheral region from sections of the metallization layer.
